(19) United States
(12) Patent Application Publication
(10) Pub. No.: US 2024/0136210 A1
(43) Pub. Date: Apr. 25, 2024

(54) LOAD LOCK CHAMBER AND APPARATUS FOR TREATING SUBSTRATE

(71) Applicant: PSK INC., Gyeonggi-do (KR)

(72) Inventors: Jong-Chan LEE, Gyeonggi-do (KR); Hyo-Won PARK, Gyeonggi-do (KR); Seok-June YUN, Gyeonggi-do (KR); Tae-Hoon LEE, Gyeonggi-do (KR)

(21) Appl. No.: 18/278,678

(22) PCT Filed: Nov. 1, 2021
(86) PCT No.: PCT/KR2021/015720

§ 371 Date: Aug. 23, 2023

(30) Foreign Application Priority Data
Feb. 24, 2021 (KR) 10-2021-0024482

(51) Int. Cl. H01L 21/67; H01L 21/68

(52) U.S. Cl. CPC H01L 21/67201; H01L 21/67069; H01L 21/67253; H01L 21/681

(57) ABSTRACT

Provided is an apparatus for treating a substrate, the apparatus including: an equipment front end module including a load port and a transfer frame; a process chamber for performing a process treatment on a substrate; and a load lock chamber disposed in a transfer path of the substrate transferred between the transfer frame and the process chamber, in which the load lock chamber includes: a housing having an interior space; a compartmentalizing plate for compartmentalizing the interior space into a first space, and a second space independent of the first space; and an aligning unit for aligning a notch of the substrate provided in any one of the first space and the second space.

### TECHNICAL FIELD

The present invention relates to a load lock chamber and an apparatus for treating a substrate.

### BACKGROUND ART

Plasma refers to an ionized gas state formed of ions, radicals, electrons, and the like, and is generated by a very high temperature, strong electric fields, or RF electromagnetic fields. A semiconductor device manufacturing process includes an ashing or etching process that uses plasma to remove a film on a substrate. The ashing or etching process is performed by ion and radical particles contained in the plasma colliding or reacting with a film on the substrate.

A device that processes a substrate by using plasma may be utilized to remove a film on the substrate (for example, a hard mask formed on the substrate, or a photoresist film formed on the substrate). The treatment of a substrate using plasma is performed in a process chamber. In order to properly treat a substrate in the process chamber, a notch direction of the substrate entering the process chamber needs to match a preset direction, and a position where the substrate is placed need to match a preset position. Accordingly, in general, a substrate is transferred to an alignment chamber provided with an aligning unit for aligning the notch of the substrate, the notch of the substrate is aligned in the aligning unit, and the notch-aligned substrate is transferred to a process chamber.

Additionally, once the substrate has been treated with plasma, it is important to verify that the treatment was performed properly. This is because it is necessary to sort out the substrate that are not being processed properly and, in some cases, it is necessary to change the setup of the device processing the substrate. In general, after treating the substrate with plasma, the substrate is transferred to an inspection chamber provided with an inspection unit that inspects the treated substrate, the inspection unit checks the treatment status of the substrate, and the substrate with the confirmed treatment status is transferred to a container, such as a FOUP. Alternatively, the substrate processed in the process chamber is stored in a FOUP, and the FOUP is transferred to a separate inspection unit to verify the treatment status of the substrate at the inspection unit.

However, as described above, when the substrate is transferred to the alignment chamber, the notch of the substrate is aligned in the alignment chamber, and the substrate is transferred from the alignment chamber to the process chamber, the transfer sequence is complex and the time required for transfer increases.

In addition, when the treated substrate is transferred to the inspection chamber and the inspection chamber checks the treatment status of the substrate as described above, the transfer sequence is complicated and the time required for transfer increases.

Further, when the treated substrate is stored in the container and the container is returned to a separate inspection unit to check the treatment status of the substrate as described above, lots of time consumes to verify the treatment status of the substrate (that is, lots of time consumes to detect anomalies in substrate processing early), and in some cases, it is difficult to change the setup of the substrate treating apparatus in a quick time.

### Technical Problem

An object of the present invention is to provide a load lock chamber and an apparatus for treating a substrate that may effectively inspect a treatment status of a substrate.

Another object of the present invention is to provide a load lock chamber and an apparatus for treating a substrate that may effectively perform notch alignment of a substrate.

Another object of the present invention is to provide a load lock chamber and an apparatus for treating a substrate that may reduce the time required to align a notch of a substrate and to inspect a treatment status of a substrate.

The problem to be solved by the present invention is not limited to the above-mentioned problems, and the problems not mentioned will be clearly understood by those skilled in the art from the present specification and the accompanying drawings.

### Technical Solution

An exemplary embodiment of the present invention provides an apparatus for treating a substrate, the apparatus including: an equipment front end module including a load port and a transfer frame; a process chamber for performing a process treatment on a substrate; and a load lock chamber disposed in a transfer path of the substrate transferred between the transfer frame and the process chamber, in which the load lock chamber includes: a housing having an interior space; a compartmentalizing plate for compartmentalizing the interior space into a first space, and a second space independent of the first space; and an aligning unit for aligning a notch of the substrate provided in any one of the first space and the second space.

According to the exemplary embodiment, the aligning unit may include: a support plate for supporting the substrate; a rotating shaft for rotating the support plate; a radiating unit for radiating light to an edge region of the substrate supported on the support plate; and a light receiving unit for receiving the light radiated by the radiating unit, and for determining whether the notch of the substrate supported on the support plate is aligned based on whether the light is received.

According to the exemplary embodiment, the radiating unit and the light receiving unit may be disposed in an exterior of the housing, and at least one of the housing and the compartmentalizing plate may be provided with a view port through which the light radiated by the radiating unit is transmitted.

According to the exemplary embodiment, the radiating unit may be configured to radiate the light in a direction inclined to a top surface of the substrate supported on the support plate.

According to the exemplary embodiment, the load lock chamber may include an inspection unit for inspecting a treatment status of the substrate provided in the other one of the first space and the second space.

According to the exemplary embodiment, the inspection unit may include: a support member for supporting a substrate; a rotating member for rotating the support member; and an image acquisition member for acquiring an image of an edge region of the substrate supported on the support member.

According to the exemplary embodiment, the rotating member may include: a shaft coupled to with the support member; and a shaft housing surrounding the shaft, and the shaft and the shaft housing may be sealed by a magnetic fluid.

According to the exemplary embodiment, image acquisition member may be disposed in an exterior of the housing, and the housing may be provided with a view port for allowing the image acquisition member to acquire the image.

Another exemplary embodiment of the present invention provides a load lock chamber where an internal atmosphere switches between a vacuum pressure atmosphere and an atmospheric pressure atmosphere, the load lock chamber including: a chamber having a first space, and a second space independent of the first space; an aligning unit for aligning a notch of a substrate provided in the first space; and an inspection unit for inspecting a treatment status of the substrate provided in the second space.

According to the exemplary embodiment, the first space may be a space into which an untreated substrate requiring a treatment in a process chamber is carried, and the second space may be a space into which the substrate that has been treated in the process chamber is carried.

According to the exemplary embodiment, the aligning unit may include: a support plate for supporting the substrate; a support pad provided on a top surface of the support plate and being in contact with a lower surface of the substrate; a rotating shaft for rotating the support plate; a radiating unit for radiating light to an edge region of the substrate supported on the support plate; and a light receiving unit for receiving the light radiated by the radiating unit, and for determining whether the notch of the substrate supported on the support plate is aligned based on whether the light is received.

According to the exemplary embodiment, the support pad may be provided in the form of an O-ring or a gecko.

According to the exemplary embodiment, the radiating unit and the light receiving unit may be disposed in an exterior of the chamber, and the chamber may be provided with a view port through which the light radiated by the radiating unit is transmitted.

According to the exemplary embodiment, the radiating unit may be configured to radiate the light in a direction inclined to a top surface of the substrate supported on the support plate.

According to the exemplary embodiment, the inspection unit may include: a support member for supporting a substrate; a rotating member for rotating the support member; and an image acquisition member for acquiring an image of an edge region of the substrate supported on the support member.

According to the exemplary embodiment, the image acquisition member may be disposed in an exterior of the chamber, and the chamber may be provided with a view port allowing the image acquisition member to acquire the image.

Still another exemplary embodiment of the present invention provides an apparatus for treating a substrate, the apparatus: an equipment front end module including a load port and a transfer frame; and a treating module for receiving a substrate stored in a container placed at the load port and performing a treating process to remove a thin film from an edge region of a substrate, in which the treating module includes: a process chamber for performing a bevel etch process; a transfer chamber for transferring a substrate transferred from the equipment front end module to the process chamber; and a load lock chamber disposed between the transfer chamber and the transfer frame, and the load lock chamber includes: a chamber having a first space into which an untreated substrate is carried, and a second space which is disposed above the first space and independent of the first space, into which the substrate treated in the process chamber is carried; an aligning unit for aligning a notch of a substrate provided in the first space; and an inspection unit for inspecting a treatment status of the substrate provided in the second space.

According to the exemplary embodiment, the aligning unit may include: a support plate for supporting the substrate; a rotating shaft for rotating the support plate; a radiating unit for radiating light to an edge region of the substrate supported on the support plate; and a light receiving unit for receiving the light radiated by the radiating unit, and for determining whether the notch of the substrate supported on the support plate is aligned based on whether the light is received.

According to the exemplary embodiment, the inspection unit may include: a support member for supporting a substrate; a rotating member for rotating the support member; and an image acquisition member for acquiring an image of an edge region of the substrate supported on the support member.

According to the exemplary embodiment, the radiating unit may be configured to radiate the light in a direction inclined to a top surface of the substrate supported on the support plate, and the image acquisition member may photograph an edge region of the substrate in a direction inclined to a top surface of the substrate supported on the support member.

### Advantageous Effects

According to the embodiment of the present invention, it is possible to effectively inspect the treatment status of the substrate.

Further, according to the embodiment of the present invention, it is possible to effectively align the notch of the substrate.

Further, according to the embodiment of the present invention, it is possible to reduce the time required to align the notch of the substrate and to inspect the treatment status of the substrate.

The effect of the present invention is not limited to the foregoing effects, and the not-mentioned effects will be clearly understood by those skilled in the art from the present specification and the accompanying drawings.

### DESCRIPTION OF DRAWINGS

FIG. 1 is a diagram schematically illustrating a substrate treating apparatus according to an exemplary embodiment of the present invention.

FIG. 2 is a diagram illustrating an exemplary embodiment of the substrate treating apparatus provided to a process chamber of FIG. 1.

FIG. 3 is a diagram illustrating an embodiment of a plasma treatment process performed by the substrate treating apparatus of FIG. 2.

FIG. 4 is a diagram schematically illustrating a load lock chamber of FIG. 1.

FIG. 5 is a diagram schematically illustrating a first load lock chamber of FIG. 4.

FIG. 6 is a diagram illustrating an embodiment of a support pad of FIG. 5.

FIG. 7 is a diagram illustrating another embodiment of the support pad of FIG. 5.

FIG. 8 is a diagram illustrating another embodiment of the support pad of FIG. 5.

FIGS. 9 and 10 are diagrams illustrating aligning the notch of the substrate in the first load lock chamber of FIG. 4.

FIG. 11 is a diagram illustrating the case where the first load lock chamber of FIG. 4 inspects the treatment status of the substrate.

FIG. 12 is a diagram illustrating an image acquired by an image acquisition member of FIG. 11.

### BEST MODE

Hereinafter, an exemplary embodiment of the present invention will be described more fully hereinafter with reference to the accompanying drawings, in which exemplary embodiments of the invention are illustrated. However, the present invention can be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element can be directly coupled to or connected to the other constituent element, but intervening elements may also be present. In contrast, when one constituent element is “directly coupled to” or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

Hereinafter, an exemplary embodiment of the present invention will be described more fully hereinafter with reference to the accompanying drawings, in which exemplary embodiments of the invention are illustrated. However, the present invention can be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

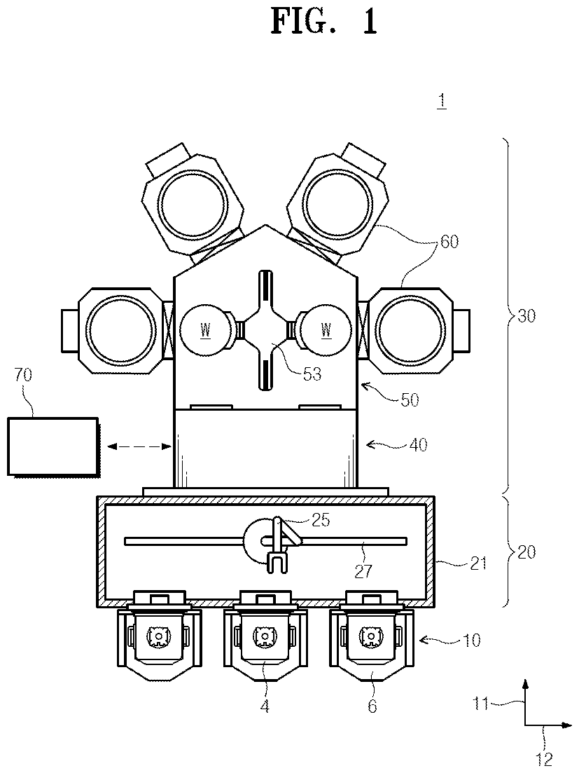

Hereinafter, an exemplary embodiment of the present invention will be described in detail with reference to FIGS. 1 to 12.

FIG. 1 is a diagram schematically illustrating a substrate treating apparatus according to an exemplary embodiment of the present invention. Referring to FIG. 1, a substrate treating apparatus 1 includes an equipment front end module (EFEM) 20, a treating module 30, and a controller 70. The EFEM 20 and the treating module 30 are disposed in one direction.

The EFEM 20 includes a load port 10 and a transfer frame 21. The load port 10 is disposed in front of the EFEM 20 in a first direction 11. The load port 10 includes a plurality of support parts 6. The support parts 6 are disposed in series in a second direction 12, and a carrier 4 (for example, a cassette, and an FOUP) in which a substrate W that is to be provided for a process and a processing completed substrate W is accommodated is seated on each support part 6. In the carrier 4, the substrate W that is to be provided for a process and the process completed substrate W are accommodated. The transfer frame 21 is disposed between the load port 10 and the treating module 30. The interior space of the transfer frame 21 may be maintained in a largely atmospheric atmosphere. The transfer frame 21 includes a first transfer robot 25 which is disposed in the interior of the transfer frame 21 and transfers the substrate W between the load port 10 and the treating module 30. The first transfer robot 25 moves along a transfer rail 27 provided in the second direction 12 to transfer the substrate W between the carrier 4 and the treating module 30.

The treating module 30 includes a load lock chamber 40, a transfer chamber 50, and a process chamber 60. The treating module 30 may treat the substrate W by receiving the substrate W from the EFEM 20. The treating module 30 may receive the substrate accommodated in a container, such as the carrier 4, placed at the load port 10 and perform a treating process to remove a thin film from an edge region of the substrate.

The load lock chamber 40 is disposed to be adjacent to the transfer frame 21. For example, the load lock chamber 40 may be disposed between the transfer chamber 50 and the EFEM 20. The load lock chamber 40 may be disposed between the transfer chamber 50 and the transfer frame 210. The load lock chamber 40 provides a place in which the substrate W to be provided for the process stands by before being transferred to the process chamber 60, or the processing completed substrate W stands by before being transferred to the EFEM 20. The atmosphere of the interior space of the load lock chamber 40 may be switched between an atmospheric pressure atmosphere and a vacuum pressure atmosphere. The load lock chamber 40 will be described in more detail later.

The transfer chamber 50 may transfer the substrate W. The transfer chamber 50 is disposed to be adjacent to the load lock chamber 40. The transfer chamber 50 has a polygonal body when viewed from above. Referring to FIG. 1, the transfer chamber 50 has a pentagonal body when viewed from above. At the external side of the body, the load lock chamber 40 and the plurality of process chambers 60 are disposed along a circumference of the body. A passage (not illustrated) through which the substrate W enters and exists is formed on each sidewall of the body, and the passage connects the transfer chamber 50 and the load lock chamber 40 or the process chambers 60. Each passage is provided with a door (not illustrated) which opens/closes the passage to seal the interior. A second transfer robot 53 which transfers the substrate W between the load lock chamber 40 and the process chambers 60 may be disposed in an internal space of the transfer chamber 50. The second transfer robot 53 transfers the untreated substrate W waiting in the load lock chamber 40 to the process chamber 60 or transfers the process completed substrate W to the load lock chamber 40. Further, the second transfer robot 53 may bring the substrate W into a treatment space 102 of a housing 100 which is to be described below, or take out the substrate W from the treatment space 102. Further, the second transfer robot 53 may transfer the substrate W between the process chambers 60 in order to sequentially provide the plurality of process chambers 60 with the substrate W. As illustrated in FIG. 1, when the transfer chamber 50 has the pentagonal body, the load lock chamber 40 is disposed on the sidewall adjacent to the EFEM 20, and the process chambers 60 are consecutively disposed on the remaining sidewalls. The transfer chamber 50 may be provided in various forms depending on a demanded process module, as well as the foregoing shape. Additionally, the internal atmosphere of the transfer chamber 50 may be maintained as a largely vacuum pressure atmosphere.

The process chamber 60 may be disposed to be adjacent to the transfer chamber 50. The process chambers 60 are disposed along the circumference of the transfer chamber 50. The plurality of process chambers 60 may be provided. In each process chamber 60, the process processing may be performed on the substrate W. The process chamber 60 may receive the substrate W from the second transfer robot 53 and perform the process processing, and provides the second transfer robot 53 with the substrate W for which the process processing is completed. The process processing performed in the respective process chambers 60 may be different from each other.

The controller 70 may control the substrate treating apparatus 1. The controller 70 may control the configurations of the substrate treating apparatus 1. The controller 70 may control the configurations of the substrate treating apparatus 1 so that the substrate treating apparatus 1 may perform a treating process on the substrate W, a notch alignment process on the substrate W, and an inspection process on the substrate W. Further, the controller 70 may include a process controller formed of a microprocessor (computer) that executes the control of the substrate treating apparatus 1, a user interface formed of a keyboard in which an operator performs a command input operation or the like in order to manage the substrate treating apparatus 1, a display for visualizing and displaying an operation situation of the substrate treating apparatus 1, and the like, and a storage unit storing a control program for executing the process executed in the substrate treating apparatus 1 under the control of the process controller or a program, that is, a treatment recipe, for executing the process in each component according to various data and processing conditions. Further, the user interface and the storage unit may be connected to the process controller. The treating recipe may be stored in a storage medium in the storage unit, and the storage medium may be a hard disk, and may also be a portable disk, such as a CD-ROM or a DVD, or a semiconductor memory, such as a flash memory.

Hereinafter, a substrate treating apparatus 1000 performing a plasma process in the process chamber 60 will be described. Further, the present invention will be described based on the example in which the substrate treating apparatus 1000 is configured to perform a plasma treating process on an edge region of a substrate among the process chambers 60. Further, the present invention will be described based on the example in which the substrate treating apparatus 1000 is configured to perform a bevel etch process for removing a thin film on an edge region of the substrate in the process chambers 60. However, the present invention is not limited thereto, and the substrate treating apparatus 1000 which is to be described below may be equally or similarly applied to various chambers in which substrate processing is performed. Further, the substrate treating apparatus 1000 may be equally or similarly applied to various chambers in which a plasma treating process is performed on the substrate.

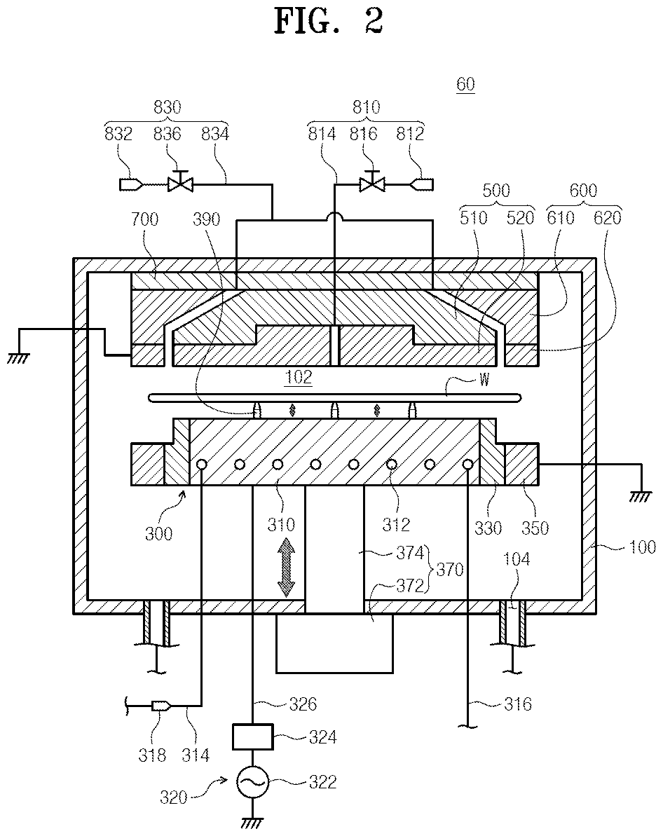

FIG. 2 is a diagram illustrating an exemplary embodiment of the substrate treating apparatus provided to the process chamber of FIG. 1. Referring to FIG. 2, the substrate treating apparatus 1000 provided in the process chamber 60 performs a predetermined process on the substrate W by using plasma. For example, the substrate treating apparatus 1000 may etch or ash a membrane on the substrate W. The membrane may be various types of membrane, such as a poly silicon film, a silicon oxide film, a silicon nitride film. Further, the membrane may be a natural oxide film or a chemically produced oxide film. Further, the membrane may be a by-product generated in a process of processing the substrate W. Further, the membrane may be impurities attached and/or left on the substrate W.

The substrate treating apparatus 1000 may perform a plasma process on the substrate W. For example, the substrate treating apparatus 1000 may supply process gas and generate plasma from the supplied process gas to treat the substrate W. The substrate treating apparatus 1000 may supply process gas and generate plasma from the supplied process gas to treat an edge region of the substrate W. Hereinafter, the substrate treating apparatus 1000 will be described as a bevel etch apparatus that performs an etching treatment on an edge region of the substrate W by way of example.

The substrate treating apparatus 1000 may include a housing 100, a support unit 300, a dielectric plate unit 500, an upper electrode unit 600, a temperature adjustment plate 700, and a gas supply unit 800.

The housing 100 may have a treatment space 102 therein. An opening (not shown) may be formed in one surface of the housing 100. The substrate W may enter or exit from the treatment space 102 of the housing 100 through the opening formed in the housing 100. The opening may be opened and closed by an opening member, such as a door (not shown). When the opening in the housing 100 is opened and closed by the opening member, the treatment space 102 of the housing 100 may be isolated from the outside. Additionally, the atmosphere in the treatment space 102 of the housing 100 may be adjusted to a low pressure near vacuum after being isolated from the outside. Further, the housing 100 may be made of a material including metal. Further, the housing 100 may have a surface thereof coated with an insulating material.

Further, the housing 100 may be a vacuum chamber. For example, an exhaust hole 104 may be formed in a bottom surface of the housing 100. Plasma P generated in the treatment space 212 or gas G1 and G2 supplied to the treatment space 102 may be exhausted to the outside through the exhaust hole 104. Further, by-products generated in the process of processing the substrate W by using the plasma P may be discharged to the outside through the exhaust hole 104. Additionally, the exhaust hole 104 may be connected to an exhaust line (not shown). The exhaust line may be connected to a decompression member that provides decompression. The decompression member may provide decompression to the treatment space 102 via an exhaust line.

Additionally, the housing 100 may include a view port 106. The view port 106 may be a port which is provided in a transparent material to allow an operator to visually view the treatment space 102 of the housing 100, or a port through which light L from a radiating unit 210, which will be described later, may be transmitted. The view port 106 may be provided on a sidewall of the housing 100. The view ports 106 may be provided in pairs facing each other. Additionally, the view port 106 may be provided at a height that is lower than the height of the lower surface of a dielectric plate 520, which is described below, and at a height that is higher than the top surface of a chuck 310.

The support unit 200 may support the substrate W in the treating space 102. The support unit 300 may include a chuck 310, a power member 320, an insulating ring 330, a lower electrode 350, a driving member 370, and a lift pin 390.

The chuck 310 may support the substrate W in the treating space 102. The chuck 310 may have a support surface supporting the substrate W. The chuck 310 may have a circular shape when viewed from above. The chuck 310 may have a diameter smaller than a diameter of the substrate W when viewed above. Accordingly, a center region of the substrate W supported by the chuck 310 is seated on the support surface of the chuck 310, and an edge region of the substrate W may not be in contact with the support surface of the chuck 310.

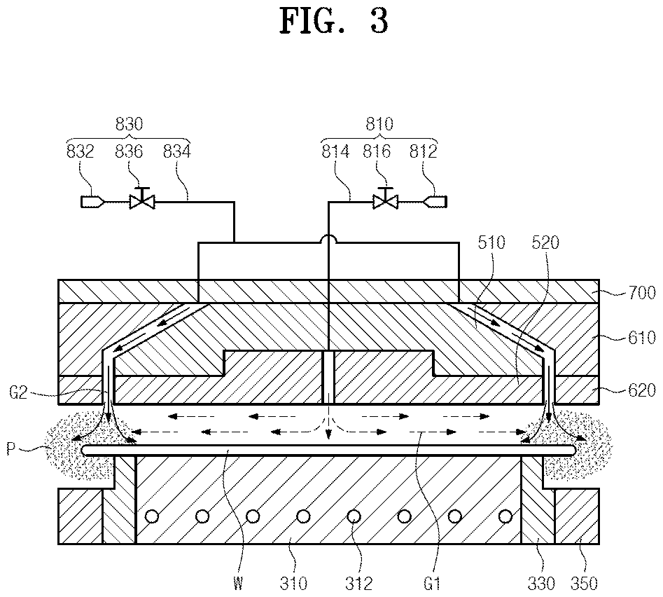

A heating means (not illustrated) may be provided inside the chuck 310. The heating means (not illustrated) may heat the chuck 310. The heating means may be a heater. Further, a cooling flow path 312 may be formed in the chuck 310. The cooling flow path 312 may be formed inside the chuck 310. A cooling fluid supply line 314 and a cooling fluid discharge line 316 may be connected to the cooling flow path 312. The cooling fluid supply line 314 may be connected with a cooling fluid supply source 318. The cooling fluid supply source 318 may store a cooling fluid and/or supply a cooling fluid to the cooling fluid supply line 314. Further, the cooling fluid supplied to the cooling flow path 312 may be discharged to the outside through the cooling fluid discharge line 316. The cooling fluid stored in and/or supplied by the cooling fluid supply source 318 may be cooling water or cooling gas. Further, the shape of the cooling flow path 312 formed in the chuck 310 is not limited to the shape illustrated in FIG. 3 and may be varied. Further, the configuration of cooling the chuck 310 is not limited to the configuration of supplying the cooling fluid, and may also be provided with various configurations (for example, a cooling plate) which are capable of cooling the chuck 310.

The power member 320 may provide power to the chuck 310. The power supply member 320 may include a power supply 322, a matcher 324, and a power supply line 326. The power supply 322 may be a bias power supply. Further, the power supply 332 may be an RF power supply. The power supply 322 may be connected with the chuck 310 via the power supply line 326. Further, the matcher 324 is provided to the power supply line 326 to perform impedance matching.

The insulating ring 330 may be provided to have a ring shape when viewed from above. For example, the insulating ring 330 may be provided to surround the chuck 310 when viewed from above. For example, the insulating ring 330 may have a ring shape. Further, the insulating ring 330 may be stepped such that a height of the top surface of the inner region is different from a height of the top surface of the outer region. For example, the insulating ring 330 may be stepped so that a height of the top surface of the inner region is higher than a height of the top surface of the outer region. When the substrate W is seated on the support surface of the chuck 310, the upper surface of the inner region between the upper surface of the inner region and the upper surface of the outer region of the insulating ring 330 may be in contact with the bottom surface of the substrate W. Further, when the substrate W is seated on the support surface of the chuck 310, the top surface of the outer region between the upper surface of the inner region and the top surface of the outer region of the insulating ring 330 may be spaced apart from the bottom surface of the substrate W. The insulating ring 330 may be provided between the chuck 310 and the lower electrode 350 described later. Since the chuck 310 is provided with a bias power source, the insulating ring 330 may be provided between the chuck 310 and the lower electrode 350 which is to be described below. The insulating ring 330 may be made of a material having an insulating property.

The lower electrode 350 may be disposed below the edge region of the substrate W supported on the chuck 310. The lower electrode 350 may be provided to have a ring shape when viewed from above. The lower electrode 350 may be provided to surround the insulating ring 330 when viewed from above. The top surface of the lower electrode 350 may be provided at the same height as that of the outer top surface of the insulating ring 330. The lower surface of the lower electrode 350 may be provided at the same height as the lower surface of the insulating ring 330. Additionally, the top surface of the lower electrode 350 may be provided lower than the top surface of the center portion of the chuck 310. Additionally, the lower electrode 350 may be provided to be spaced apart from the bottom surface of the substrate W supported on the chuck 310. For example, the lower electrodes 350 may be provided to be spaced apart from the bottom surface of the edge region of the substrate W supported on the chuck 310.

The lower electrode 350 may be disposed to face the upper electrode 620 which is to be described later. The lower electrode 350 may be disposed under the upper electrode 620 which is to be described below. The lower electrode 350 may be grounded. The lower electrode 350 may increase the plasma density by inducing coupling of the bias power applied to the chuck 310. Thus, the processing efficiency for the edge region of the substrate W may be improved.

The driving member 370 may lift the chuck 310. The driving member 370 may include a driver 372 and a shaft 374. The shaft 374 may be coupled with the chuck 310. The shaft 374 may be connected with the driver 372. The driver 372 may move up and down the chuck 310 in the vertical direction via the shaft 374.

The lift pin 3325 may move the substrate W in the vertical direction. The lift pin 390 may be moved in the up and down direction by a separate driver (not shown). The lift pin 390 may be moved up and down through pin holes (not shown) formed in the chuck 310. Additionally, a plurality of lift pins 390 may be provided. For example, a plurality of lift pins 390 may be provided to support the lower surface of the substrate and elevate the substrate W at different locations.

The dielectric plate unit 500 may include the dielectric plate 520 and a first base 510. Further, the dielectric plate unit 500 may be coupled to a temperature adjustment plate 700 which is to be described below.

The dielectric plate 520 may be disposed so that a lower surface thereof faces an upper surface of the chuck 310. The dielectric plate 520 may have a circular shape when viewed from above. Further, the upper surface of the dielectric plate 520 may be stepped so that a height of a center region thereof is greater than a height of the edge region. Further, the lower surface of the dielectric plate 520 may be provided in a flat shape. The dielectric plate 520 may be disposed opposite the substrate W supported by the support unit 300 in the treating space 102. The dielectric plate 520 may be disposed above the support unit 300. The dielectric plate 520 may be made of a material including ceramic. A gas flow path connected with a first gas supply unit 810 of the gas supply unit 800, which will be described below, may be formed in the dielectric plate 520. Further, a discharge end of the gas flow path may be configured so that first gas G1 supplied by the first gas supply unit 810 is supplied to the center region of the substrate W supported by the support unit 300. Further, the discharge end of the gas flow path may be configured so that the first gas G1 is supplied to the upper surface of the center region of the substrate W supported by the support unit 300.

The first base 510 may be disposed between the dielectric plate 520 and the temperature adjustment plate 700 which is to be described below. The first base 510 may be coupled to the temperature adjustment plate 700 which is to be described below, and the dielectric plate 520 may be coupled to the first base 510. Accordingly, the dielectric plate 520 may be coupled to the temperature adjustment plate 700 via the first base 510.

The diameter of the first base 510 may gradually increase from top to bottom. The diameter of the upper surface of the first base 510 may be smaller than the diameter of the lower surface of the dielectric plate 520. The upper surface of the first base 510 may have a flat shape. Further, a lower surface of the first base 510 may have a stepped shape. For example, the lower surface of the first base 510 may be stepped so that a height of the lower surface of the edge region of the first base 510 is smaller than a height of the lower surface of the center region. Further, the lower surface of the first base 510 and the upper surface of the dielectric plate 520 may have shapes that may be combined with each other. For example, the center region of the dielectric plate 520 may be inserted into the center region of the first base 510. Further, the first base 510 may be made of a material including metal. For example, the first base 510 may be made of a material including aluminum.

The upper electrode unit 600 may include a second base 610, and the upper electrode 620. Further, the upper electrode unit 600 may be coupled to the temperature adjustment plate 700, which is described later.

The upper electrode 620 may be opposed to the lower electrode 350 described above. The upper electrode 620 may be disposed above the lower electrode 350. The upper electrode 620 may be disposed in the upper portion of the edge region of the substrate W supported on the chuck 310. The upper electrode 620 may be grounded.

The upper electrode 620 may have a shape that surrounds the dielectric plate 520 when viewed from above. The upper electrode 620 may be provided to be spaced apart from the dielectric plate 520. The top electrode 620 may be spaced apart from the dielectric plate 520 to form a space. The space may form a part of the gas channel in which the second gas G2 supplied by the second gas supply unit 830, which will be described below, flows. A discharge end of the gas channel may be configured so that the second gas G2 is supplied to the edge region of the substrate W supported by the support unit 300. Further, the discharge end of the gas channel may be configured so that the second gas G2 is supplied to the upper surface of the edge region of the substrate W supported by the support unit 300.

The second base 610 may be disposed between the upper electrode 620 and the temperature adjustment plate 700 which is to be described later. The second base 610 may be coupled to the temperature adjustment plate 700 which is to be described later, and the upper electrode 620 may be coupled to the second base 610. Accordingly, the upper electrode 620 may be coupled to the temperature adjustment plate 700 via the second base 610.

The second base 610 may have a ring shape when viewed from above. The top surface and the lower surface of the second base 610 may have a flat shape. When viewed from above, the second base 610 may have a shape surrounding the first base 510. An inner diameter of the second base 610 may gradually increase from top to bottom. The second base 610 may be provided to be spaced apart from the first base 510. The second base 610 may be spaced apart from the first base 510 to form a space. The space may form a part of the gas channel in which the second gas G2 supplied by the second gas supply unit 830, which will be described below, flows. Further, the second bas 610 may be made of a material including metal. For example, the second base 610 may be made of a material including aluminum.

The temperature adjustment plate 700 may be coupled with the dielectric plate unit 500 and the upper electrode unit 600. The temperature adjustment plate 700 may be installed in the housing 100. The temperature adjustment plate 700 may generate heat. For example, the temperature adjustment plate 700 may generate hot or cold heat. The temperature adjustment plate 700 may generate heat by receiving a signal from the controller 900, which is described later. The temperature adjustment plate 700 may generate hot or cold heat, so that the temperature of the dielectric plate unit 500 and the upper electrode unit 600 may be controlled to remain relatively constant. For example, the temperature adjustment plate 700 generates cold heat, so that the temperature of the dielectric plate unit 500 and the upper electrode unit 600 may be suppressed as much as possible from becoming excessively high in the process of treating the substrate W.

The gas supply unit 800 may supply gas to the treating space 102. The gas supply unit 800 may supply first gas G1 and second gas G2 to the treating space 102. The gas supply unit 800 may include a first gas supply unit 810 and a second gas supply unit 830.

The first gas supply 810 may supply the first gas G1 to the treating space 102. The first gas G1 may be inert gas, such as nitrogen. The first gas supply unit 810 may supply the first gas G1 to the center region of the substrate W supported by the chuck 310. The first gas supply unit 810 may include a first gas supply source 812, a first gas supply line 814, and a first valve 816. The first gas supply source 812 may store the first gas G1 and/or supply the first gas G1 to the first gas supply line 814. The first gas supply line 814 may be connected with the flow path formed in the dielectric plate 520. The first valve 816 may be installed in the first gas supply line 814. The first valve 816 may be an on/off valve, or provided as a flow rate adjustment valve. The first gas G1 supplied by the first gas supply source 812 may be supplied to the center region of the upper surface of the substrate W through the flow path formed in the dielectric plate 520.

The second gas supply unit 830 may supply the second gas G2 to the treating space 102. The second gas G2 may be process gas excited to a plasma state. The second gas supply unit 830 may supply the second gas G2 to the edge region of the substrate W through a gas channel formed by the dielectric plate 520, the first base 510, the top electrode 620, and the second base 610 spaced apart from each other above the edge region of the substrate W supported on the chuck 310. The second gas supply unit 830 may include a second gas supply source 832, a second gas supply line 834, and a second valve 836. The second gas supply source 832 may store the second gas G2 and/or supply the second gas G2 to the second gas supply line 834. The second gas supply line 814 may supply the second gas G2 to the space functioning as the gas channel. The second valve 836 may be installed in the second gas supply line 834. The second valve 836 may be an on/off valve, or provided as a flow rate adjustment valve. The second gas G2 supplied by the second gas supply source 832 may be supplied to the edge region of the top surface of the substrate W through the second flow path 602.

FIG. 3 is a diagram illustrating an embodiment of a plasma treatment process performed by the substrate treating apparatus of FIG. 2. Referring to FIG. 3, the substrate treating apparatus 1000 according to the embodiment of the present invention may treat an edge region of the substrate W. For example, the substrate treating apparatus 1000 may process the edge region of the substrate W by generating plasma P in the edge region of the substrate W. For example, the substrate treating apparatus 1000 may perform a bevel etch process of processing the edge region of the substrate W. When the substrate treating apparatus 1000 process the edge region of the substrate W, the first gas supply unit 810 may supply the first gas G1 to a center region of the substrate W and the second gas supply unit 830 may supply the second gas G2 to the edge region of the substrate W. The second gas G2 supplied by the second gas supply unit 830 is process gas, so that the second gas G2 may be excited in a plasma P state to treat the edge region of the substrate W. For example, a thin film on the edge region of the substrate W may be etching-processed by the plasma P. Further, the first gas G1 supplied to the center region of the substrate W is inert gas, and the first gas G1 prevents the second gas G2 from being introduced to the center region of the substrate W, thereby further improving treating efficiency for the edge region of the substrate W. In addition, the temperature adjustment plate 700 may generate cold heat so that the temperature of the dielectric plate unit 500 and the upper electrode unit 600 may be suppressed from increasing excessively while performing the treatment on the substrate W.

According to the exemplary embodiment of the present invention, the first base 510 is disposed between the dielectric plate 520 and the temperature adjustment plate 700. The first base 510 may be made of a material different from that of the dielectric plate 520 and may be made of the same material as that of the temperature adjustment plate 700. That is, a thermal expansion coefficient of the first base 510 may be closer to a thermal expansion coefficient of the temperature adjustment plate 700 than a thermal expansion coefficient of the dielectric plate 520. That is, the first base 510 is disposed between the dielectric plate 520 and the temperature adjustment plate 700, so that it is possible to minimize distortion generated between the temperature adjustment plate 700 and the dielectric plate 520 due to cooling heat generated by the temperature adjustment plate 700. This is because the first base 510 that is in direct contact with the temperature adjustment plate 700 is made of a material similar to that of the temperature adjustment plate 700.

Similarly, in the embodiment of the present invention, the second base 610 is disposed between the upper electrode 620 and the temperature adjustment plate 700. The second base 610 may be provided of a different material than the upper electrode 620, and may be provided of the same material as the temperature adjustment plate 700. That is, the thermal expansion coefficient of the second base 610 may be closer to the thermal expansion coefficient of the temperature adjustment plate 700 than the thermal expansion coefficient of the upper electrode 620. In other words, as the second base 610 is disposed between the upper electrode 620 and the temperature adjustment plate 700, so that distortion may be minimized between the temperature adjustment plate 700 and the upper electrode 620 due to cold heat generated by the temperature adjustment plate 700. This is because the second base 610 that is in direct contact with the temperature adjustment plate 700 is made of the material similar to that of the temperature adjustment plate 700.

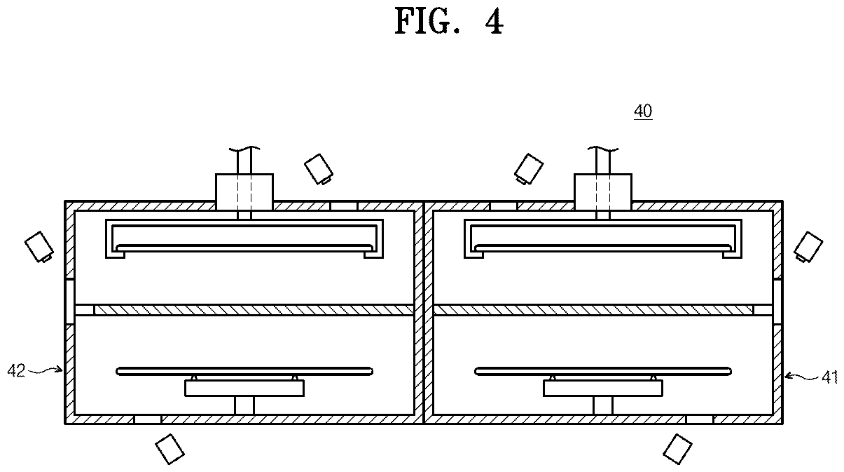

FIG. 4 is a diagram schematically illustrating a load lock chamber of FIG. 1. In particular, FIG. 4 is a diagram illustrating a cross-section of the load lock chamber 40 of FIG. 1. The load lock chamber 40 may include a first load lock chamber 41 and a second load lock chamber 42. The first load lock chamber 41 and the second load lock chamber 42 may be disposed side by side along the second direction 12. The first load lock chamber 41 and the second load lock chamber 42 may have a symmetrical structure. Since the first load lock chamber 41 and the second load lock chamber 42 have a substantially similar structure, hereinafter, the first load lock chamber 41 will be described and the description of the second load lock chamber 42 will be omitted.

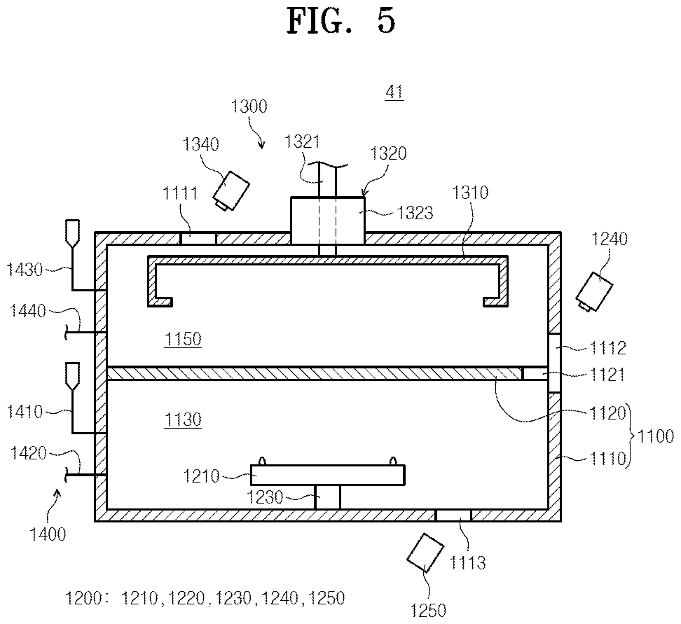

FIG. 5 is a diagram schematically illustrating the first load lock chamber of FIG. 4. Referring to FIG. 5, the first load lock chamber 41 may include a chamber 1100, an aligning unit 1200, an inspection unit 1300, and an atmosphere switching unit 1400.

The chamber 1100 may have an interior space. The interior space of the chamber 1100 may include a first space 1130 and a second space 1150. Additionally, the chamber 1100 may be formed with doors (not illustrated) that selectively communicate the interior space of the transfer frame 21 with the first space 1130 or the second space 1150. Additionally, the chamber 1100 may be formed with doors (not illustrated) that selectively communicate the interior space of the transfer chamber 50 with the first space 1130 or the second space 1150.

Additionally, the first space 1130 and the second space 1150 may be independent of each other. For example, the chamber 1100 may include a housing 1110, and a compartmentalizing plate 1120. The compartmentalizing plate 1120 may compartmentalize the interior space of the housing 1100 into a first space 1130 and a second space 1150. The internal atmosphere of the first space 1130 and the second space 1150 may be switched between an atmospheric pressure atmosphere and a vacuum pressure atmosphere by the atmosphere switching unit 1400, described later.

Additionally, the second space 1150 may be disposed above the first space 1130. The first space 1130 may be the space into which the substrate W, in which the treatment in the process chamber 60 is required, that is, the untreated substrate W, is carried. For example, the first space 1130 may be a space in which the untreated substrate W, which has been carried out from the carrier 4, is carried. Additionally, the second space 1150 may be a space in which the substrate W that has been processed in the process chamber 60 is carried. For example, the second space 1150 may be a space in which the treated substrate W that has been carried out from the process chamber 60 is carried. The controller 70 may control the first transfer robot 25 and the second transfer robot 53 to carry the untreated substrate W into and out of the first space 1130 and transfer the substrate W to the process chamber 60, and carry the processed substrate W into and out of the second space 1150 and transfer the substrate W to the carrier 4.

Additionally, the chamber 1000 may be provided with a plurality of view ports. For example, the housing 1110 may be provided with a first view port 1111, a second view port 1112, and a third view port 1113. The first view port 1111 may be provided with a transparent material. The first view port 1111 may be provided at a location adjacent to an image acquisition member 1340 which will be described later. The first view port 1111 may be provided on a top wall of the housing 1110. The second view port 1112 may be provided with a transparent material. The second view port 1112 may be provided at a location adjacent to a radiating unit 1240 which will be described later. The second view port 1112 may be provided on a sidewall of the housing 1110. The third view port 1113 may be provided with a transparent material. The third view port 1113 may be provided at a location adjacent to a light receiving unit 150 described later. The third view port 1113 may be provided on a lower wall of the housing 1110. Additionally, the compartmentalizing plate 1120 may be provided with a fourth view port 1121. The fourth view port 1121 may be provided with a transparent material. The fourth view port 1121 may be disposed adjacent to the radiating unit 1240 and the second view port 1121.

The aligning unit 1200 may align the notch N of the substrate W provided in either of the first space 1130 and the second space 1150. The aligning unit 1200 may align the notch N of the substrate W provided in the first space 1130. The aligning unit 1200 may include a support plate 1210, a support pad 1220, a rotating shaft 1230, the radiating unit 1240, and the light receiving unit 1250.

The support plate 1210 may support the substrate W. The support plate 1210 may have a smaller diameter than the substrate W when viewed from above. That is, the support plate 1210 may support the center region of the substrate W between the center region and the edge region of the substrate W. The top surface of the support plate 1210 may also be coupled with a rotating shaft 1230 that may be rotated by a driver, such as a motor. Accordingly, the support plate 1210 may be rotated by the rotating shaft 1230. Accordingly, the substrate W supported on the support plate 1210 may be rotated. The driver (not shown) that rotates the rotating shaft 1230 may be disposed in the exterior of the chamber 1110. That is, the rotating shaft 1230 may be inserted into a hole formed in the housing 1100, and the space between the housing 1110 and the rotating shaft 1230 may be sealed using a magnetic fluid.

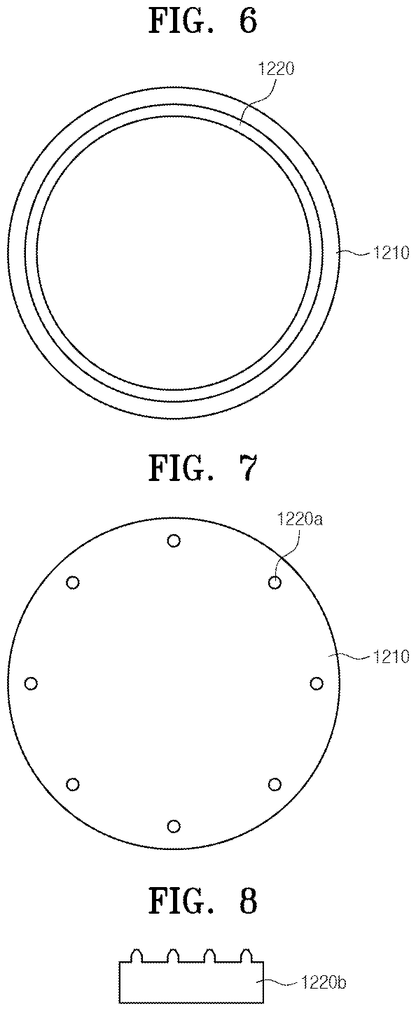

Additionally, the support pad 1220 may be provided on a top surface of the support plate 1210. The support pad 1220 may contact the lower surface of the substrate W when the substrate W is placed on the support plate 1210. The support pad 1220 may be provided with a material, such as rubber, to prevent the substrate W from sliding (to prevent the substrate W from slipping) when the substrate W is rotated. Additionally, the support pad 1220 may also be provided with a material including carbon-filled polyetheretherketone (PEEK). Additionally, the support pad 1220 may be provided as an adhesive pad. To more easily prevent the substrate W from slipping, the support pad 1220 may have an O-ring shape (see FIG. 6). However, without limitation, the top surface of the support plate 1210 may be provided with a support pad 1220a including protrusions, as shown in FIG. 7. Additionally, to more easily prevent the substrate W from slipping, the top surface of the support plate 1210 may be provided with a support pad 1220b, which may be provided in the form of a gecko as shown in FIG. 8. The support pad 1220b provided in the form of a gecko has a shape similar to the paw pads of a lizard, which may minimize slippage of the substrate W due to contamination, residue, outgassing, adhesives, and reactions when supporting the substrate W.

Referring again to FIG. 5, the radiation unit 1240 may radiate light. The radiation unit 1240 may radiate light toward the light receiving unit 1250. The light radiated by the radiating unit 1240 may be light that is generally straight (for example, laser), but is not limited to thereto and may be varied. The light receiving unit 1250 may receive light radiated by the radiation unit 1240. The controller 70 or the light receiving unit 1250 determines whether the notch N of the substrate W placed on the support plate 1210 is properly aligned based on whether the light receiving unit 1250 is receiving light. Additionally, the radiating unit 1240 and the light receiving unit 1250 may be disposed in the exterior of the chamber 1100.

Light radiated by the radiation unit 1240 may pass through the second view port 1112 and/or the fourth view port 1121. Additionally, light radiated by the radiation unit 1240 may pass through the third view port 1113. That is, the second view port 1120, the third view port 1113, and the fourth view port 1121 may be disposed in the radiation path of the light radiated by the radiation unit 1240. Further, the radiating unit 1240 may radiate light in an inclined direction with respect to the top surface of the substrate W placed on the support plate 1210. When the substrate W is placed on the support plate 1210, it is possible that the substrate W is placed in a somewhat inaccurate position. When the radiating unit 1240 radiates light in an inclined direction, the area irradiated by the light becomes wider in the top surface of the substrate W, so that even though the substrate W is placed in a somewhat inaccurate position, it is possible to determine the alignment of the notch N.

The inspection unit 1300 may inspect the treatment status of the substrate W provided in the other of the first space 1130 and the second space 1150. The inspection unit 1300 may inspect the treatment status of the substrate W provided in the second space 1150. The inspection unit 1300 may include a support member 1310, a rotating member 1320, and an image acquisition member 1340.

The support member 1310 may be rotated by the rotating member 1320. The support member 212 may support the edge region of the substrate W. The support member 1310 may support the lower surface of the substrate W. The support member 1310 may be provided with a transparent material depending on cases. The rotating member 1320 may rotate the support member 1310. The rotating member 1320 may include a shaft 1321 coupled to the support member 1310, and a shaft housing 1323 surrounding the shaft 1321. A driver (for example, a drive motor) to rotate the shaft 1321 may be disposed in the exterior of the chamber 1100. Additionally, the shaft housing 1323 may be inserted into a center region of the upper wall of the housing 1110. The area between the shaft housing 1323 and the shaft 1321 may be sealed using a magnetic fluid, similar to the rotating shaft 1230 described above. The second space 1150 may have an atmosphere that may be switched between an atmospheric pressure atmosphere and a vacuum pressure atmosphere, and by sealing the second space 1150 by using a magnetic fluid, the rotational motion of the shaft 1321 may be transmitted to the second space 1150, which may have a vacuum pressure atmosphere.

The image acquisition member 1340 may acquire an image that may check the treatment status of the substrate W treated in the process chamber 60. The image acquisition member 1340 may be a camera. The image acquisition member 1340 may photograph the substrate W to acquire an image of the edge region of the substrate W. The image acquisition member 1340 may acquire an image of the top surface of the substrate W. The image acquisition member 1340 may acquire an image of the edge region of the substrate W provided in the second space 1150 through the first view port 1111. Additionally, the image acquisition member 1340 may capture the edge region of the substrate W in a direction inclined to the top surface of the substrate supported on the support member 1310. In this case, the image acquisition member 1340 may acquire the image of the wider edge region of the substrate W.

The atmosphere switching unit 1400 may switch the atmosphere of the interior space of the chamber 1100 between a vacuum pressure atmosphere and an atmospheric pressure atmosphere. The atmosphere switching unit 1400 may include a first gas supply line 1410 supplying gas to the first space 1130, a first gas exhaust line 1420 exhausting the atmosphere of the first space 1130, a second gas supply line 1430 supplying gas to the second space 1150, and a second gas exhaust line 1440 exhausting the atmosphere of the second space 1150. The gas supplied by the first gas supply line 1410 and the second gas supply line 1430 may be inert gas such as nitrogen or argon.

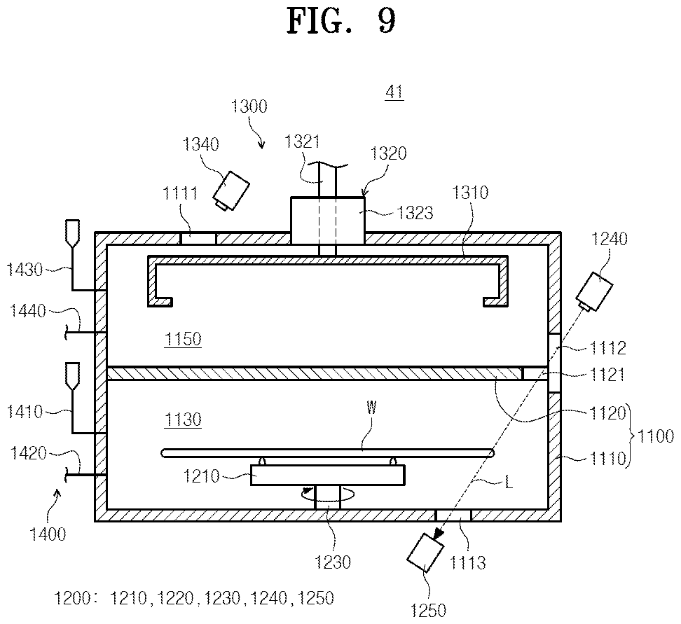

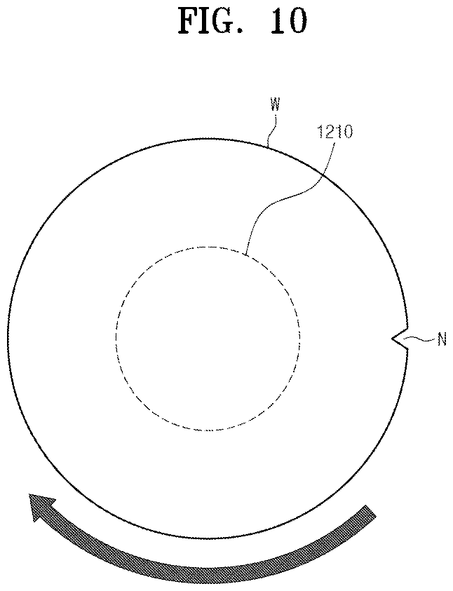

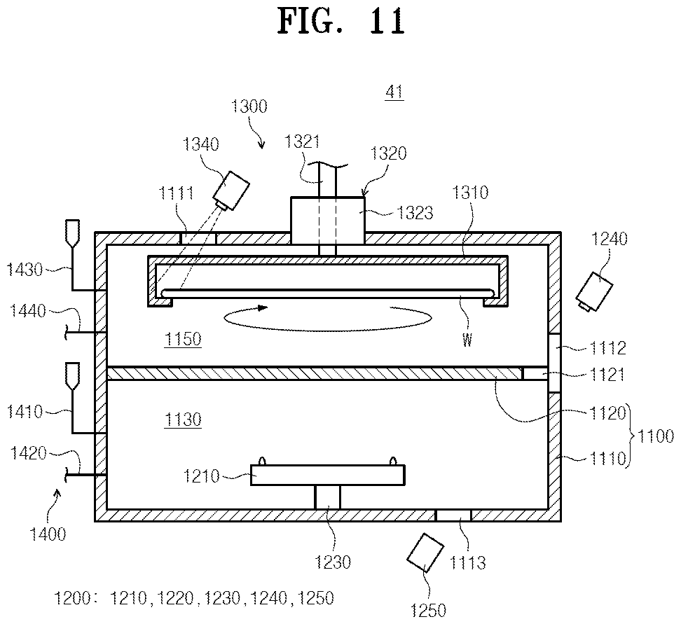

FIGS. 9 and 10 are diagrams illustrating aligning the notch of the substrate in the first load lock chamber of FIG. 4. Referring to FIGS. 9 and 10, when the untreated substrate W is carried in the first space 1130, the radiating unit 1240 may radiate the light L. The light L may be radiated toward the light receiving unit 1250. In this case, when the notch N in the substrate W is not properly aligned, the light receiving unit 1250 may not be able to receive light L. In this case, the rotating shaft 1230 may slowly rotate the support plate 1210, thereby rotating the substrate W. When the substrate W is rotated so that the notch N formed in the substrate W is properly aligned, the light receiving unit 1250 may receive light L. In this case, the notch N of the substrate W is determined to be properly aligned, and the substrate W may be transferred from the load lock chamber 40 to the transfer chamber 50. The alignment of the notch N may be performed during the switching of the atmosphere of the first space 1130, or after the switching is complete, or before the switching.

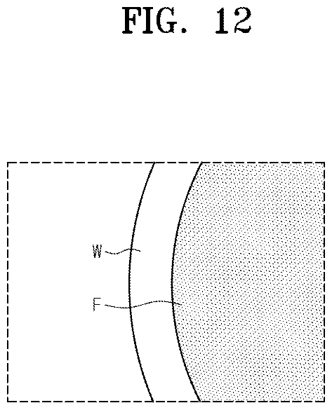

FIG. 11 is a diagram illustrating the case where the first load lock chamber of FIG. 4 inspects the treatment status of the substrate, and FIG. 12 is a diagram illustrating the image acquired by the image acquisition member of FIG. 11. Referring to FIGS. 11 and 12, the thin film F on the edge region of the substrate W of which the treatment is completed in the process chamber 60 may be removed. When the substrate W treated in the process chamber 60 is carried into the second space 1150, the substrate W may be supported by the support member 1310. In this case, the image acquisition member 1340 may acquire an image of the edge region of the substrate W to check the treatment status of the substrate W. The photographing of the substrate W by the image acquisition member 1340 may occur continuously while the support member 1310 is rotated. Alternatively, multiple images of the edge region of the substrate W may be acquired by sequentially repeating the photographing and the rotation. The image acquisition may be performed during the switching of the atmosphere of the second space 1150, after the switching is complete, or before the switching.

In order to transfer the substrate W between the carrier 4 and the process chamber 60, the substrate W passes through the load lock chamber 40, which inevitably results in a wait time for the substrate W in the load lock chamber 40. According to the embodiment of the present invention, the load lock chamber 40 includes the aligning unit 1200 that aligns the notch N in the substrate W. Accordingly, the notch N of the substrate W may be aligned while the substrate W is waiting in the load lock chamber 40, thereby reducing the time required to transfer the substrate W to a separate alignment chamber to align the notch N of the substrate W. In addition, the load lock chamber 40 includes the inspection unit 1300 that inspects the treatment status of the substrate W. Accordingly, the treatment status of the substrate W may be checked while the substrate W is waiting in the load lock chamber 40. Accordingly, the time required to transfer the substrate W to check the treatment status of the substrate W may be reduced. In addition, when the substrate W is not treated properly, the operator may immediately check this, and in some cases, the operator may immediately change the setup of the substrate treating apparatus 1. In other words, according to the embodiment of the present invention, it is possible to increase production and inspect the substrate W.

In the foregoing example, the present invention has been described based on the case where the aligning unit 1130 aligns the substrate W provided in the first space 1130 as an example, but the present invention is not limited thereto. For example, the aligning unit 1130 may be configured to align the substrate W provided in the second space 1130.

In the foregoing example, the present invention has been described based on the case where the chamber 1100 is provided in the two-layer structure including the first space 1130 and the second space 1150 as an example, but the present invention is not limited thereto. For example, the chamber 1100 may also be provided in a multi-layer structure.

In the foregoing example, the present invention has been described based on the case where the inspection unit 1300 is configured to acquire the image of the top surface of the substrate W as an example, but the present invention is not limited thereto. For example, the inspection unit 1300 may be configured to acquire an image of the lower surface of the substrate W provided in the second space 1150.

In the foregoing example, the present invention has been described based on the case where the support pad 1220 has an O-ring shape or a gecko shape as an example, but the present invention is not limited thereto. For example, the top surface of the support pad 1220 may be flat, or may have an inclined shape.

In the foregoing example, the present invention has been described based on the case where the aligning units 1200 are provided on the same floor, and the inspection units 1300 are provided on the same floor as an example, but the present invention is not limited thereto. For example, the aligning unit 1200 and the inspection unit 1300 may be provided on the same floor.

The foregoing detailed description illustrates the present invention. Further, the above content illustrates and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in the specific application field and use of the present invention are possible. Accordingly, the detailed description of the invention above is not intended to limit the invention to the disclosed exemplary embodiment. Further, the accompanying claims should be construed to include other exemplary embodiments as well.

1. An apparatus for treating a substrate, the apparatus comprising:
an equipment front end module including a load port and a transfer frame;
a process chamber for performing a process treatment on a substrate; and
a load lock chamber disposed in a transfer path of the substrate transferred between the transfer frame and the process chamber,
wherein the load lock chamber includes:
a housing having an interior space;
a compartmentalizing plate for compartmentalizing the interior space into a first space, and a second space independent of the first space; and
an aligning unit for aligning a notch of the substrate provided in any one of the first space and the second space.

2. The apparatus of claim 1, wherein the aligning unit includes:
a support plate for supporting the substrate;
a rotating shaft for rotating the support plate;
a radiating unit for radiating light to an edge region of the substrate supported on the support plate; and
a light receiving unit for receiving the light radiated by the radiating unit, and for determining whether the notch of the substrate supported on the support plate is aligned based on whether the light is received.

3. The apparatus of claim 2, wherein the radiating unit and the light receiving unit are disposed in an exterior of the housing, and
at least one of the housing and the compartmentalizing plate is provided with a view port through which the light radiated by the radiating unit is transmitted.

4. The apparatus of claim 3, wherein the radiating unit is configured to radiate the light in a direction inclined to a top surface of the substrate supported on the support plate.

5. The apparatus of claim 1, wherein the load lock chamber includes an inspection unit for inspecting a treatment status of the substrate provided in the other one of the first space and the second space.

6. The apparatus of claim 5, wherein the inspection unit includes:
a support member for supporting a substrate;
a rotating member for rotating the support member; and
an image acquisition member for acquiring an image of an edge region of the substrate supported on the support member.

7. The apparatus of claim 6, wherein the rotating member includes:
a shaft coupled to with the support member; and
a shaft housing surrounding the shaft, and
the shaft and the shaft housing are sealed by a magnetic fluid.

8. The apparatus of claim 6, wherein the image acquisition member is disposed in an exterior of the housing, and
the housing is provided with a view port for allowing the image acquisition member to acquire the image.

9. A load lock chamber where an internal atmosphere switches between a vacuum pressure atmosphere and an atmospheric pressure atmosphere, the load lock chamber comprising:
a chamber having a first space, and a second space independent of the first space;
an aligning unit for aligning a notch of a substrate provided in the first space; and
an inspection unit for inspecting a treatment status of the substrate provided in the second space.

10. The load lock chamber of claim 9, wherein the first space is a space into which an untreated substrate requiring a treatment in a process chamber is carried, and
the second space is a space into which the substrate that has been treated in the process chamber is carried.

11. The load lock chamber of claim 9, wherein the aligning unit includes:
a support plate for supporting the substrate;
a support pad provided on a top surface of the support plate and being in contact with a lower surface of the substrate;
a rotating shaft for rotating the support plate;
a radiating unit for radiating light to an edge region of the substrate supported on the support plate; and
a light receiving unit for receiving the light radiated by the radiating unit, and for determining whether the notch of the substrate supported on the support plate is aligned based on whether the light is received.

12. The load lock chamber of claim 11, wherein the support pad is provided in the form of an O-ring or a gecko.

13. The load lock chamber of claim 11, wherein the radiating unit and the light receiving unit are disposed in an exterior of the chamber, and
the chamber is provided with a view port through which the light radiated by the radiating unit is transmitted.

14. The load lock chamber of claim 13, wherein the radiating unit is configured to radiate the light in a direction inclined to a top surface of the substrate supported on the support plate.

15. The load lock chamber of claim 9, wherein the inspection unit includes:
a support member for supporting the substrate;
a rotating member for rotating the support member; and
an image acquisition member for acquiring an image of an edge region of the substrate supported on the support member.

16. The load lock chamber of claim 15, wherein the image acquisition member is disposed in an exterior of the chamber, and
the chamber is provided with a view port allowing the image acquisition member to acquire the image.

17. An apparatus for treating a substrate, the apparatus comprising:
an equipment front end module including a load port and a transfer frame; and
a treating module for receiving a substrate stored in a container placed at the load port and performing a treating process to remove a thin film from an edge region of a substrate,
wherein the treating module includes:
a process chamber for performing a bevel etch process;
a transfer chamber for transferring a substrate transferred from the equipment front end module to the process chamber; and
a load lock chamber disposed between the transfer chamber and the transfer frame, and
the load lock chamber includes:
a chamber having a first space into which an untreated substrate is carried, and a second space which is disposed above the first space and independent of the first space, into which the substrate treated in the process chamber is carried;
an aligning unit for aligning a notch of a substrate provided in the first space; and
an inspection unit for inspecting a treatment status of the substrate provided in the second space.

18. The apparatus of claim 17, wherein the aligning unit includes:
a support plate for supporting the substrate;
a rotating shaft for rotating the support plate;
a radiating unit for radiating light to an edge region of the substrate supported on the support plate; and
a light receiving unit for receiving the light radiated by the radiating unit, and for determining whether the notch of the substrate supported on the support plate is aligned based on whether the light is received.

19. The apparatus of claim 18, wherein the inspection unit includes:
a support member for supporting the substrate;
a rotating member for rotating the support member; and
an image acquisition member for acquiring an image of an edge region of the substrate supported on the support member.

20. The apparatus of claim 19, wherein the radiating unit is configured to radiate the light in a direction inclined to a top surface of the substrate supported on the support plate, and
the image acquisition member photographs an edge region of the substrate in a direction inclined to a top surface of the substrate supported on the support member.
